(19) United States
(12) Patent Application Publication
(10) Pub. No.: US 2026/0224020 A1
(43) Pub. Date: Aug. 6, 2026

(54) BRUSH CLEANING APPARATUS

(71) Applicant: SAMSUNG ELECTRONICS CO., LTD., Suwon-si (KR)

(72) Inventors: Jihee YANG, Suwon-si (KR); Donghoon KWON, Suwon-si (KR)

(73) Assignee: SAMSUNG ELECTRONICS CO., LTD., Suwon-si (KR)

(21) Appl. No.: 19/456,138

(22) Filed: Jan. 22, 2026

(30) Foreign Application Priority Data
Feb. 6, 2025 (KR) 10-2025-0015333

(51) Int. Cl. A46B 17/06; A46B 13/00; A46B 13/02; B03C 1/02; B08B 3/02; B08B 3/14; B08B 5/04; H10P 72/00

(52) U.S. Cl. CPC A46B 17/06; A46B 13/001; A46B 13/02; B03C 1/02; B08B 3/024; B08B 3/14; B08B 5/04; A46B 2200/3073; B03C 2201/18; H10P 72/0412

(57) ABSTRACT

A brush cleaning apparatus includes a sprayer including a spray nozzle configured to spray a cleaning solution including a plurality of magnetic particles and a carrier fluid onto a brush, and a spray pipe in communication with the spray nozzle, a suction device including a suction nozzle configured to suck the cleaning solution disposed on an outer surface of the brush, and a suction pipe in communication with the suction nozzle, and a purifier connected to the spray pipe of the sprayer and the suction pipe of the suction device and configured to separate the plurality of magnetic particles from the cleaning solution.

### CROSS-REFERENCE TO RELATED APPLICATION

This application is based on and claims priority under 35 U.S.C. § 119 to Korean Patent Application No. 10-2025-0015333, filed on Feb. 6, 2025, in the Korean Intellectual Property Office, the disclosure of which is incorporated by reference herein in its entirety.

### BACKGROUND

The inventive concept relates to a brush cleaning apparatus, and more particularly, to a brush cleaning apparatus using a cleaning solution including magnetic particles.

In the semiconductor manufacturing process, a cleaning process is essential to remove fine contaminants present on a surface of a semiconductor substrate. In particular, a cleaning process using a brush that directly contacts and washes the semiconductor substrate is widely used due to its high cleaning effect. However, in the cleaning process using a brush, contaminants may remain on the brush, and the semiconductor substrate may be re-contaminated by the contaminants remaining on the brush. Accordingly, research is continuously being conducted on methods of cleaning the brush to minimize re-contamination of the semiconductor substrate.

### SUMMARY

The inventive concept provides a brush cleaning apparatus for cleaning a brush by using a cleaning solution including magnetic particles.

However, the inventive concept is not limited to the mentioned above, and other inventive concepts can be clearly understood by those skilled in the art from the following description.

According to an aspect of the inventive concept, there is provided a brush cleaning apparatus including a sprayer including a spray nozzle configured to spray a cleaning solution including a plurality of magnetic particles and a carrier fluid onto a brush, and a spray pipe in communication with the spray nozzle, a suction device including a suction nozzle configured to suck the cleaning solution disposed on an outer surface of the brush, and a suction pipe in communication with the suction nozzle, and a purifier connected to the spray pipe of the sprayer and the suction pipe of the suction device and configured to separate the plurality of magnetic particles from the cleaning solution.

According to another aspect of the inventive concept, there is provided a brush cleaning apparatus including a sprayer including a plurality of spray nozzles configured to spray a cleaning solution containing a plurality of magnetic particles and a carrier fluid onto a brush, and a spray pipe in communication with the plurality of spray nozzles, a suction device including a plurality of suction nozzles configured to suck the cleaning solution located on an outer surface of the brush, and a suction pipe in communication with the plurality of suction nozzles, and a purifier connected to the spray pipe of the sprayer and the suction pipe of the suction device and configured to separate the plurality of magnetic particles from the cleaning solution. The plurality of spray nozzles of the sprayer include a first spray nozzle and a second spray nozzle, and the plurality of suction nozzles of the suction device include a first suction nozzle configured to suck the cleaning solution sprayed from the first spray nozzle, and a second suction nozzle configured to suck the cleaning solution sprayed from the second spray nozzle.

According to another aspect of the inventive concept, there is provided a brush cleaning apparatus including a sprayer including at least one spray nozzle configured to spray a cleaning solution including a plurality of magnetic particles and a carrier fluid onto a brush, and a spray pipe in communication with the at least one spray nozzle, a suction device including at least one suction nozzle configured to suck the cleaning solution located on an outer surface of the brush, a suction pipe in communication with the at least one suction nozzle, and a suction magnetic body located on the at least one suction nozzle, and a purifier including a frame including a processing space in communication with the spray pipe of the sprayer and the suction pipe of the suction device, and a purifying magnetic body configured to form a magnetic field in the processing space. The brush includes a body in a cylindrical shape, and a brush magnetic body extending in a long axis direction of the body and passing through the body, and each of the brush magnetic body of the brush, the suction magnetic body of the suction device, and the purifying magnetic body of the purifier is configured to apply an attractive force to the plurality of magnetic particles of the cleaning solution.

### BRIEF DESCRIPTION OF THE DRAWINGS

Embodiments will be more clearly understood from the following detailed description taken in conjunction with the accompanying drawings in which:

FIG. 1 is a schematic plan view of a brush cleaning apparatus according to embodiments;

FIG. 2 is a schematic side view of the brush cleaning apparatus according to embodiments;

FIG. 3 is a schematic cross-sectional view of a purifier of the brush cleaning apparatus, according to embodiments;

FIG. 4 is a schematic plan view of a brush CB to be cleaned by the brush cleaning apparatus, according to embodiments;

FIG. 5 is a schematic plan view of a brush to be cleaned by the brush cleaning apparatus, according to embodiments;

FIG. 6 is a schematic plan view of a brush to be cleaned by the brush cleaning apparatus, according to embodiments;

FIG. 7 is a schematic plan view of a brush to be cleaned by the brush cleaning apparatus, according to embodiments;

FIG. 8 is a schematic plan view of a brush to be cleaned by the brush cleaning apparatus, according to embodiments;

FIG. 9 is a schematic plan view of a brush cleaning apparatus according to embodiments;

FIG. 10 is a schematic plan view of a brush cleaning apparatus according to embodiments;

FIG. 11 is a schematic conceptual of a brush cleaning apparatus according to embodiments; and

FIG. 12 is a schematic conceptual diagram of a brush cleaning apparatus according to embodiments.

### DETAILED DESCRIPTION OF THE EMBODIMENTS

Embodiments are provided to fully explain the inventive concept to those skilled in the art and are modifiable in various forms. In addition, the scope of the inventive concept is not limited to the embodiments below. The embodiments are rather provided to make the inventive concept more thorough and complete and fully convey the inventive concept to those skilled in the art.

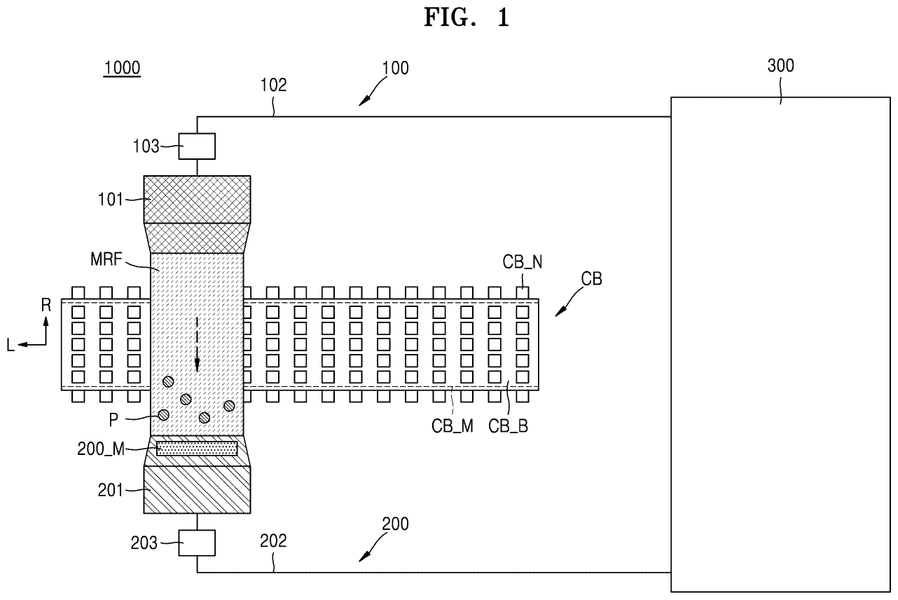

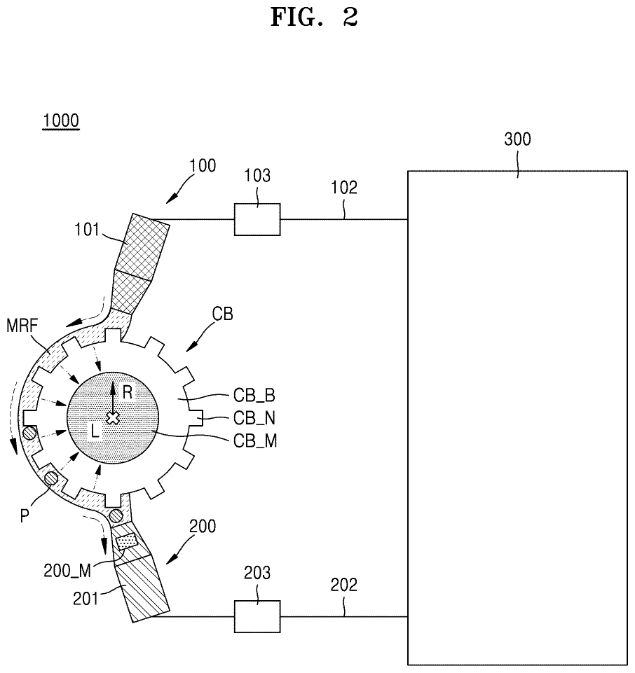

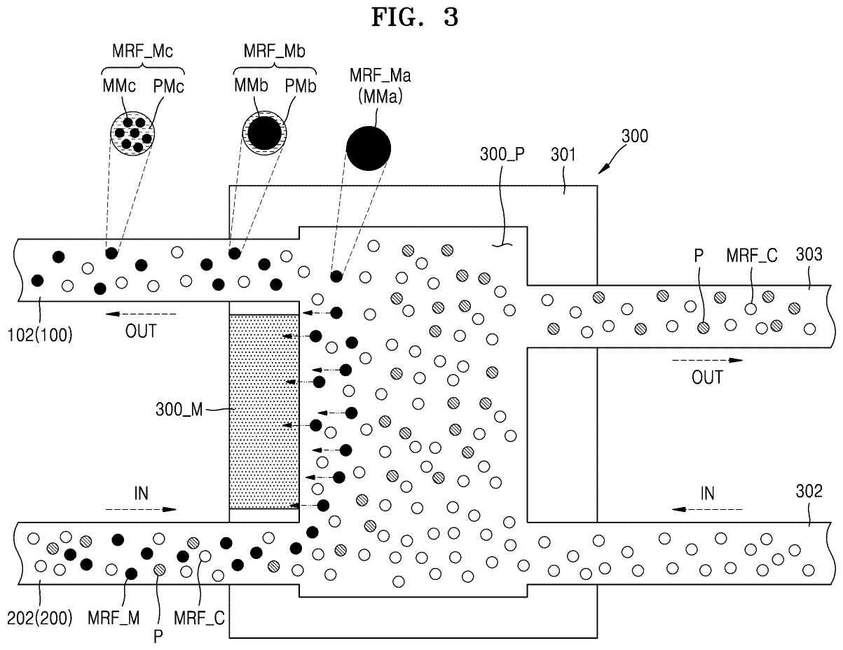

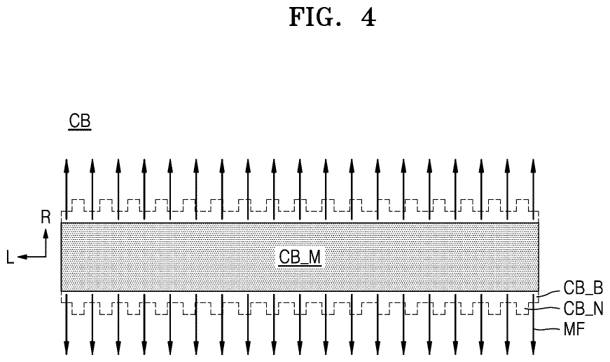

FIG. 1 is a schematic plan view of a brush cleaning apparatus 1000 according to embodiments. FIG. 2 is a schematic side view of the brush cleaning apparatus 1000 according to embodiments. FIG. 3 is a schematic cross-sectional view of a purifier 300 of the brush cleaning apparatus 1000, according to embodiments. FIG. 4 is a schematic plan view of a brush CB to be cleaned by the brush cleaning apparatus 1000, according to embodiments.

Referring to FIGS. 1 to 4, the brush cleaning apparatus 1000 may include a sprayer 100, a suction device 200, and the purifier 300. The brush cleaning apparatus 1000 may spray a cleaning solution MRF including a plurality of magnetic particles MRF_M onto the brush CB to clean the brush CB in a non-contact manner.

For example, as the brush cleaning apparatus 1000 sprays the cleaning solution MRF onto the brush CB through the sprayer 100, the cleaning solution MRF may move along the outer surface of the brush CB and may be sucked by the suction device 200. While the cleaning solution MRF moves along the outer surface of the brush CB, impurities P attached to the outer surface of the brush CB may move together with the cleaning solution MRF and may be sucked into the suction device 200.

The cleaning solution MRF and the impurities P sucked by the suction device 200 may flow into the purifier 300. The purifier 300 may separate the plurality of magnetic particles MRF_M of the cleaning solution MRF from the impurities P and then discharge the cleaning solution MRF to the sprayer 100.

The brush cleaning apparatus 1000 is economically efficient in that the brush cleaning apparatus 1000 purifies and reuses the cleaning solution MRF through the purifier 300. In addition, the brush cleaning apparatus 1000 is capable of suppressing brush re-contamination where the impurities P are re-attached to the brush CB.

The sprayer 100 of the brush cleaning apparatus 1000 may include a spray nozzle 101 and a spray pipe 102 in communication with the spray nozzle 101. For example, one end of the spray pipe 102 may be connected to the spray nozzle 101, and the other end of the spray pipe 102 may also be connected to the purifier 300. For example, the spray pipe 102 may provide a path for the cleaning solution MRF to flow.

The spray nozzle 101 may be positioned to spray the cleaning solution MRF onto the brush CB to be cleaned by the brush cleaning apparatus 1000. For example, the spray nozzle 101 may be spaced apart from the brush CB in a diametric direction R of the brush CB. In some embodiments, the spray nozzle 101 may be arranged such that an inlet of the spray nozzle 101 faces the brush CB. In some embodiments, the spray nozzle 101 may be arranged to be inclined downward.

In some embodiments, the sprayer 100 may further include a spray pump 103. The spray pump 103 may apply an external force to cause the cleaning solution MRF to flow from the purifier 300 to the spray nozzle 101. The spray pump 103 may include one of a gear pump, a piston pump, a turbine pump, a rotary pump, and a vane pump. For example, the spray pump 103 may adjust the flow rate of the cleaning solution MRF sprayed from the spray nozzle 101.

The cleaning solution MRF used in the brush cleaning apparatus 1000 may include the plurality of magnetic particles MRF_M and a carrier fluid MRF_C. The cleaning solution MRF may include a magnetorheological fluid. In some embodiments, each of the plurality of magnetic particles MRF_M may include magnet plastic (PANICNQ), magnetite (Fe₃O₄), cobalt iron oxide (CoFe₂O₄), or neodymium. In some embodiments, the carrier fluid MRF_C may include silicone oil, mineral oil, or synthetic oil. In some embodiments, the cleaning solution MRF may further include an antioxidant and a viscosity modifier.

The plurality of magnetic particles MRF_M are described in detail with reference to FIG. 3.

The plurality of magnetic particles MRF_M may include a first type of magnetic particles MRF_Ma, a second type of magnetic particles MRF_Mb, and a third type of magnetic particles MRF_Mc. For example, the cleaning solution MRF may include only one type of magnetic particles among the first type of magnetic particles MRF_Ma, the second type of magnetic particles MRF_Mb, and the third type of magnetic particles MRF_Mc. However, the inventive concept is not limited thereto. The cleaning solution MRF may include a mixture of at least two types of magnetic particles among the first type of magnetic particles MRF_Ma, the second type of magnetic particles MRF_Mb, and the third type of magnetic particles MRF_Mc.

The first type of magnetic particles MRF_Ma may include one particle composed only of magnetic material MMa. The first type of magnetic particles MRF_Ma may expose the magnetic material MMa to the outside.

The second type of magnetic particles MRF_Mb may include a magnetic material MMb, and a non-magnetic material PMb surrounding the magnetic material MMb. For example, the second type of magnetic particles MRF_Mb may have a shape where a film made of the non-magnetic material PMb surrounds one particle made of the magnetic material MMb. For example, the outer surface of the magnetic material MMb of the second type of magnetic particles MRF_Mb may not be exposed to the outside. For example, the non-magnetic material PMb of the second type of magnetic particles MRF_Mb may be conformally formed on the magnetic material MMb of the second type of magnetic particles MRF_Mb. In some embodiments, the non-magnetic material PMb may include polyvinyl alcohol PVA.

The third type of magnetic particles MRF_Mc may be formed by mixing a magnetic material MMc with a non-magnetic material PMc. For example, the third type of magnetic particles MRF_Mc may have a shape where a plurality of nanoparticles made of the magnetic material MMc are dispersed inside one particle made of the non-magnetic material PMc. In some embodiments, the non-magnetic material PMc may include the polyvinyl alcohol PVA.

Referring back to FIGS. 1 and 2, due to the viscosity of the cleaning solution MRF, the carrier fluid MRF_C may be moved by the movement of the plurality of magnetic particles MRF_M, thereby changing the flow direction of the cleaning solution MRF. As the cleaning solution MRF is magnetized in a magnetic field MF (see FIG. 4) by the plurality of magnetic particles MRF_M included in the cleaning solution MRF, the flow direction of the cleaning solution MRF may be changed by the magnetic field MF.

The flow direction of the cleaning solution MRF may be changed due to the magnetic field MF generated in a brush magnetic body CB_M of the brush CB. For example, the cleaning solution MRF may flow along the outer surface of the brush CB. For example, as the plurality of magnetic particles MRF_M of the cleaning solution MRF are attracted to the brush magnetic body CB_M located inside the brush CB, the cleaning solution MRF may not fall off from the outer surface of the brush CB due to gravity and may be located on the outer surface of the brush CB. The cleaning solution MRF located on the outer surface of the brush CB may be pushed by the cleaning solution MRF sprayed by the sprayer 100 to move along the outer surface of the brush CB.

The brush CB to be cleaned by the brush cleaning apparatus 1000 is described in detail with reference to FIG. 4. In FIG. 4, a body CB_B of the brush CB is expressed transparently to show the brush magnetic body CB_M of the brush CB. FIG. 4 discloses a case where the brush magnetic body CB_M is a magnet.

The brush CB may include the body CB_B having a cylindrical shape, and the brush magnetic body CB_M located inside the body CB_B and extending in a long axis direction L of the body CB_B. In some embodiments, the brush magnetic body CB_M may form the magnetic field MF outside the brush CB.

In some embodiments, the brush magnetic body CB_M may have a cylindrical shape. In some embodiments, the length of the body CB_B in the long axis direction L may be substantially the same as the length of the brush magnetic body CB_M in the long axis direction L. In some embodiments, the length of the body CB_B in the diametric direction R may be greater than the length of the brush magnetic body CB_M in the diametric direction R. For example, the long axis of the body CB_B may overlap with the long axis of the brush magnetic body CB_M. The long axis direction of the body CB_B may be referred to as the long axis direction L of the brush CB.

The body CB_B of the brush CB may include a plurality of nodules CB_N located on the outer surface of the body CB_B and protruding outward. The plurality of nodules CB_N may be spaced apart from each other and evenly distributed on the outer surface of the body CB_B. For example, the cross-section of each of the plurality of nodules CB_N may be polygonal, such as square, or circular. For example, the body CB_B of the brush CB may include polyvinyl alcohol PVA.

Referring back to FIGS. 1 and 2, the suction device 200 of the brush cleaning apparatus 1000 may include a suction nozzle 201 and a suction pipe 202 in communication with the suction nozzle 201. For example, one end of the suction pipe 202 may be connected to the suction nozzle 201, and the other end of the suction pipe 202 may be connected to the purifier 300. For example, the suction pipe 202 may provide a path for the cleaning solution MRF to flow. For example, the cleaning solution MRF sucked by the suction device 200 may flow into the purifier 300 through the suction pipe 202.

The suction nozzle 201 may be positioned to suck the cleaning solution MRF located on the outer surface of the brush CB. For example, the suction nozzle 201 may be spaced apart from the brush CB in the diametric direction R of the brush CB. In some embodiments, the suction nozzle 201 may be arranged such that an inlet of the suction nozzle 202 faces the brush CB. In some embodiments, the spray nozzle 101 may be arranged to be inclined upward.

In some embodiments, the suction nozzle 201 of the suction device 200 may be positioned to correspond to the spray nozzle 101 of the sprayer 100. In some embodiments, the suction nozzle 201 and the spray nozzle 101 may be spaced apart from each other with the brush CB therebetween. For example, the suction nozzle 201 of the suction device 200 may overlap with the spray nozzle 101 of the sprayer 100 in a vertical direction. However, the inventive concept is not limited thereto. The position of the suction nozzle 201 of the suction device 200 may be changed to suck all the cleaning solution MRF sprayed from the spray nozzle 101 of the sprayer 100.

In some embodiments, an inlet of the suction nozzle 201 of the suction device 200 may be larger than the inlet of the spray nozzle 101 of the sprayer 100. For example, as the inlet of the suction nozzle 201 of the suction device 200 is larger than the inlet of the spray nozzle 101 of the sprayer 100, a portion of the cleaning solution MRF diffusing in the long axis direction L of the brush CB may be efficiently sucked.

In some embodiments, the suction device 200 may further include a suction pump 203. The suction pump 203 may generate a negative pressure in the suction nozzle 201 of the suction device 200. For example, the cleaning solution MRF located on the outer surface of the brush CB may be sucked into the suction nozzle 201 of the suction device 200 through the suction pump 203. For example, the intensity of the suction pump 203 of the suction device 200 may be adjusted to the intensity of the spray pump 103 of the sprayer 100. The suction pump 203 may include one of a gear pump, a piston pump, a turbine pump, a rotary pump, and a vane pump.

In some embodiments, the suction device 200 may further include a suction magnetic body 200_M located at the suction nozzle 201. The suction magnetic body 200_M may form the magnetic field to change the flow direction of the cleaning solution MRF. For example, the suction magnetic body 200_M may apply an attractive force to the plurality of magnetic particles MRF_M of the cleaning solution MRF. The suction magnetic body 200_M may apply the attractive force to the cleaning solution MRF located on the outer surface of the brush CB to move the cleaning solution MRF to the suction nozzle 201. For example, the intensity of the magnetic field formed by the suction magnetic body 200_M may be greater than the intensity of the magnetic field MF formed by the brush CB. In some embodiments, the suction magnetic body 200_M may include a magnet or an electromagnet.

The purifier 300 is described in detail with reference to FIG. 3.

The purifier 300 may include a frame 301 that provides a processing space 300_P therein to separate the cleaning solution MRF from the impurities P. The suction pipe 202 of the suction device 200 and the spray pipe 102 of the sprayer 100 may be connected to the frame 301 and communicate with the processing space 300_P. For example, the cleaning solution MRF and the impurities P may flow into the processing space 300_P through the suction pipe 202 of the suction device 200, the plurality of magnetic particles MRF_M of the cleaning solution MRF may be separated in the processing space 300_P, and then the plurality of magnetic particles MRF_M and the carrier fluid MRF_C may flow out to the spray pipe 102 of the sprayer 100.

In some embodiments, the cleaning solution MRF and the impurities P may flow from the processing space 300_P of the purifier 300 due to an external force generated by the spray pump 103 of the sprayer 100 or the suction pump 203 of the suction device 200.

The purifier 300 may further include a purifying magnetic body 300_M located inside the frame 301. For example, the purifying magnetic body 300_M may form the magnetic field in the processing space 300_P of the frame 301. For example, the purifier 300 may separate the plurality of magnetic particles MRF_M of the cleaning solution MRF from the impurities P through the purifying magnetic body 300_M that generates the magnetic field.

In some embodiments, the cleaning solution MRF introduced from the suction pipe 202 may pass through the magnetic field formed by the purifying magnetic body 300_M and then flow out to the spray pipe 102. For example, the purifying magnetic body 300_M may located on a first surface defining the processing space 300_P, and the suction pipe 202 and the spray pipe 102 may be spaced apart from each other with the purifying magnetic body 300_M therebetween on the first surface of the processing space 300_P.

For example, the purifying magnetic body 300_M may provide the attractive force to the plurality of magnetic particles MRF_M of the cleaning solution MRF located in the processing space 300_P. Therefore, the plurality of magnetic particles MRF_M of the cleaning solution MRF located in the processing space 300_P may be densely packed into the purifying magnetic body 300_M. For example, a region adjacent to the purifying magnetic body 300_M in the processing space 300_P may have a higher density of the plurality of magnetic particles MRF_M than other regions.

In contrast, the impurities P, which are not affected by the magnetic field generated by the purifying magnetic body 300_M, may not move to the vicinity of the purifying magnetic body 300_M. Rather, as the plurality of magnetic particles MRF_M move toward the purifying magnetic body 300_M, the impurities P may move into the space where the pressure is lowered.

In some embodiments, the purifying magnetic body 300_M may include a magnet that itself generates the magnetic field. In some embodiments, the purifying magnetic body 300_M may include an electromagnet that generates the magnetic field while being powered.

In some embodiments, the purifier 300 may further include a discharge pipe 303 configured to discharge a part of the cleaning solution MRF and the impurities P to the outside of the purifier 300. The discharge pipe 303 may communicate with the processing space 300_P of the purifier 300. For example, the substances, other than the plurality of magnetic particles MRF_M in the cleaning solution MRF, and the impurities P may be discharged to the outside of the purifier 300 through the discharge pipe 303.

In some embodiments, the purifying magnetic body 300_M may be more adjacent to the spray pipe 102 of the sprayer 100 than the discharge pipe 303. For example, the distance between the discharge pipe 303 and the purifying magnetic body 300_M may be greater than the distance between the spray pipe 102 and the purifying magnetic body 300_M. In some embodiments, the spray pipe 102 and the purifying magnetic body 300_M may be located on the first surface of the processing space 300_P, and the discharge pipe 303 may be located on a second surface opposite to the first surface of the process space 300_P.

The discharge pipe 303 may be positioned such that the distance between the discharge pipe 303 and the purifying magnetic body 300_M is relatively long, thereby preventing the plurality of magnetic particles MRF_M of the cleaning solution MRF from being discharged to the discharge pipe 303. For example, the position of the discharge pipe 303 may be adjusted such that the impurities P and the carrier fluid MRF_C of the cleaning solution MRF are discharged to the discharge pipe 303.

In some embodiments, the purifier 300 may further include a carrier fluid supply pipe 302. The carrier fluid supply pipe 302 may communicate with the processing space 300_P of the purifier 300 to supply the carrier fluid MRF_C to the processing space 300_P. For example, components of the cleaning solution MRF excluding the plurality of magnetic particles MRF_M may be provided to the processing space 300_P through the carrier fluid supply pipe 302. For example, the carrier fluid MRF_C, as well as the antioxidant and the viscosity modifier, may be provided to the processing space 300_P through the carrier fluid supply pipe 302.

As much as a part of the cleaning solution MRF is discharged from the processing space 300_P through the discharge pipe 303, a part of the clean solution MRF may be provided to the processing space 300_P through the carrier fluid supply pipe 302. For example, as the fluid discharged through the discharge pipe 303 is free of the plurality of magnetic particles MRF_M, and the fluid supplied from the carrier fluid supply pipe 302 may be free of the plurality of magnetic particles MRF_M.

The plurality of magnetic particles MRF_M of the cleaning solution MRF may only circulate through the suction device 200 and the sprayer 100. Thus, it may not be necessary to discharge and replenish the cleaning solution MRF through the discharge pipe 303 and the carrier fluid supply pipe 302. Accordingly, the cost required to replace and replenish the cleaning solution MRF may be reduced.

For example, as the plurality of magnetic particles MRF_M of the cleaning solution MRF are reused and the cleaning solution MRF is replenished with the carrier fluid MRF_C, the cleaning solution MRF in a purified state, which is free of impurities P, may be discharged through the spray pipe 102 of the sprayer 100. Therefore, the brush CB may be suppressed from being re-contaminated by the impurities P moving from the cleaning solution MRF to the brush CB.

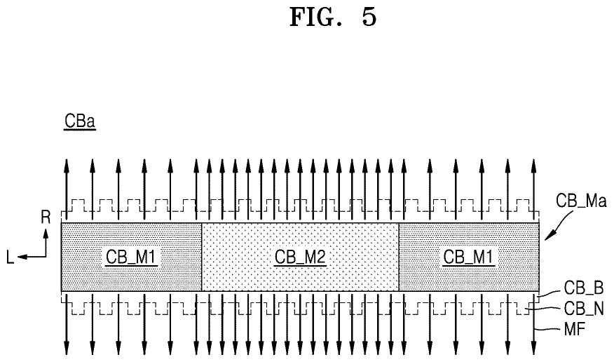

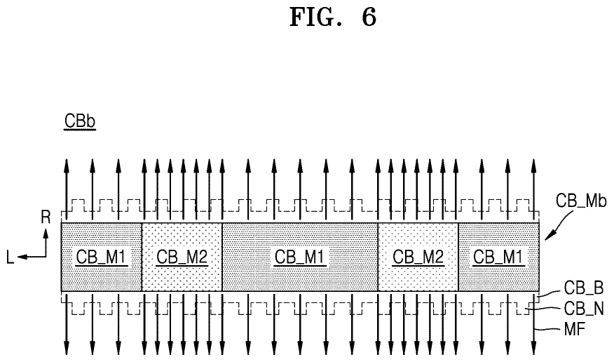

FIG. 5 is a schematic plan view of a brush CBa to be cleaned by the brush cleaning apparatus 1000, according to embodiments. FIG. 6 is a schematic plan view of a brush CBb to be cleaned by the brush cleaning apparatus 1000, according to embodiments.

In FIGS. 5 and 6, the body CB_B is drawn transparently to show brush magnetic bodies CB_Ma and CB_Mb. FIGS. 5 and 6 disclose a case where the brush magnetic bodies CB_Ma and CB_Mb are magnets.

Most components of the brushes CBa and CBb described below and materials constituting the components thereof are substantially the same as or similar to those described above with reference to FIG. 4. Therefore, for convenience of description, the differences between the brushes CBa and CBb of FIGS. 5 and 6 and the brush CB of FIG. 4 described above are mainly described below.

Referring to FIG. 5, the brush CBa may include the body CB_B having a cylindrical shape and the brush magnetic body CB_Ma positioned in the body CB_B and passing through the body CB_B of the brush CBa. The brush magnetic body CB_Ma may include a plurality of magnetic body blocks. The plurality of magnetic body blocks of the brush magnetic body CB_Ma may be arranged in a row in the long axis direction L of the brush CBa. In some embodiments, each of the plurality of magnetic body blocks may have a cylindrical shape.

The plurality of magnetic body blocks may include a pair of first magnetic body blocks CB_M1 and a second magnetic body block CB_M2. For example, the intensity of the magnetic field MF generated in the first magnetic body block CB_M1 may be different from that of the magnetic field MF generated in the second magnetic body block CB_M2. For example, the intensity of the magnetic field MF generated in the first magnetic body block CB_M1 may be less than the intensity of the magnetic field MF generated in the second magnetic body block CB_M2.

The second magnetic body block CB_M2 may be located between the pair of first magnetic body blocks CB_M1. For example, the first magnetic body block CB_M1 may be located at each of both ends of the brush CBa, and the second magnetic body block CB_M2 may be located at the center of the brush CBa. In some embodiments, the length of the first magnetic body block CB_M1 in the long axis direction L and the length of the second magnetic body block CB_M2 in the long axis direction may be independent of each other.

The brush magnetic body CB_Ma may be divided into a first section and a second section. The intensity of the magnetic field generated in the first section may be less than the intensity of the magnetic field generated in the second section. For example, the first section of the brush magnetic body CB_Ma may include a section where the pair of first magnetic body blocks CB_M1 are located, and the second section of the brush magnetic body CB_Ma may include a section where the second magnetic body block CB_M2 is located.

As the intensity of the magnetic field applied to the plurality of magnetic particles MRF_M (see FIG. 3) of the cleaning solution MRF (see FIG. 2) increases, the attractive force applied to the plurality of magnetic particles MRF_M may increase. As the brush magnetic body CB_Ma of the brush CBa includes the first magnetic body blocks CB_M1 and the second magnetic body block CB_M2 having different magnetic field intensities, the efficiency of cleaning the brush CBa by using the cleaning solution MRF may be improved. For example, the impurities P (see FIG. 3) attached to the brush CBa may be efficiently removed by positioning the second magnetic field block CB_M2 at a portion of the brush CBa, where a relatively large amount of impurities P are attached.

Referring to FIG. 6, the brush CBb may include the body CB_B having a cylindrical shape and the brush magnetic body CB_Mb positioned in the body CB_B and passing through the body CB_B of the brush CBb. The brush magnetic body CB_Mb may include the plurality of magnetic body blocks. The plurality of magnetic body blocks may have the same diameter in a cylindrical shape.

The plurality of magnetic body blocks may include a plurality of first magnetic body blocks CB_M1 and a plurality of second magnetic body blocks CB_M2. The intensity of the magnetic field of the first magnetic body block CB_M1 may be different from the intensity of the magnetic field of the second magnetic body block CB_M2. In some embodiments, the plurality of magnetic body blocks may further include a third magnetic body block, wherein the intensity of the magnetic field of the third magnetic body block is different from that of the magnetic fields of the first magnetic body block CB_M1 and the second magnetic body block CB_M2.

In some embodiments, the intensity of the magnetic field of the second magnetic body block CB_M2 may be greater than that of the magnetic field of the first magnetic body block CB_M1. The plurality of first magnetic body blocks CB_M1 and the plurality of second magnetic body blocks CB_M2 may be alternately arranged. For example, each of the plurality of second magnetic body blocks CB_M2 may be located between the plurality of first magnetic body blocks CB_M1. The plurality of second magnetic body blocks CB_M2 may be spaced apart from each other with the first magnetic body block CB_M1 therebetween.

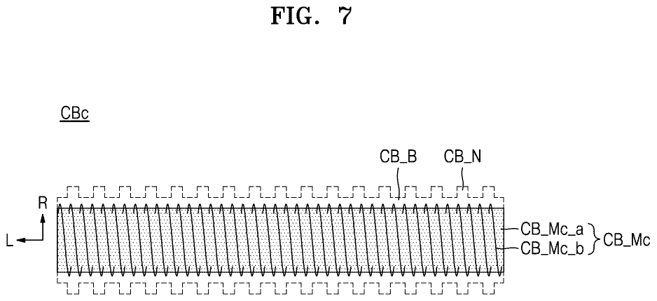

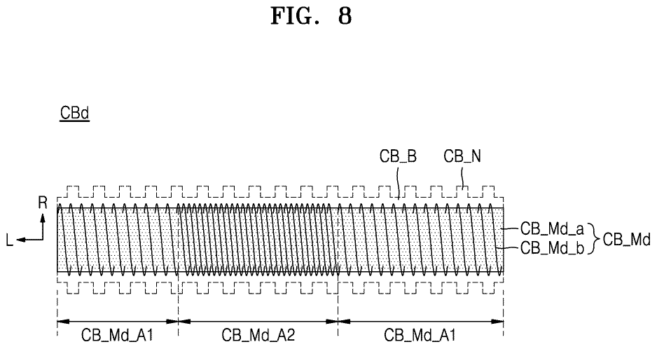

FIG. 7 is a schematic plan view of a brush CBc to be cleaned by the brush cleaning apparatus 1000, according to embodiments. FIG. 8 is a schematic plan view of a brush CBd to be cleaned by the brush cleaning apparatus 1000, according to embodiments.

In FIGS. 7 and 8, the bodies CB_B are drawn transparently to show the brush magnetic bodies CB_Mc and CB_Md. FIGS. 7 and 8 disclose a case where the brush magnetic bodies CB_Mc and CB_Md are electromagnets.

Most components of the brushes CBc and CBd described below and materials constituting the components thereof are substantially the same as or similar to those described above with reference to FIG. 4. Therefore, for convenience of description, the differences between the brushes CBc and CBd of FIGS. 7 and 8 and the brush CB of FIG. 4 described above are mainly described below.

Referring to FIG. 7, the brush magnetic body CB_Mc may include a core CB_Mc_a and a coil CB_Mc_b surrounding the core CB_Mc_a. For example, the coil CB_Mc_b may extend in a spiral shape and surround the outer surface of the core CB_Mc_a. When power is supplied to the coil CB_Mc_b of the brush magnetic body CB_Mc, the brush magnetic body CB_Mc may form the magnetic field. In some embodiments, the core CB_Mc_a may include a metal material, such as aluminum, iron, nickel, cobalt, or the like.

In some embodiments, in the process of cleaning the brush CBc, the coil CB_Mc_b of the brush magnetic body CB_Mc of the brush CBc may be powered to form the magnetic field around the brush CBc to attract the cleaning solution MRF (see FIG. 2) to the outer surface of the brush CBc.

Referring to FIG. 8, the brush magnetic body CB_Md may include a core CB_Md_a and a coil CB_Md_b surrounding the core CB_Md_a. The coil CB_Md_b may extend in a spiral shape along the outer surface of the core CB_Md_a. When a current flows through the coil CB_Md_b, the coil CB_Md_b may form the magnetic field in a direction passing through the core CB_Md_a.

The brush magnetic body CB_Md may include first sections CB_Md_A1 and a second section CB_Md_A2. The intensity of the magnetic field generated in the first section CB_Md_A1 may be less than the intensity of the magnetic field generated in the second section CB_Md_A2. For example, the more tightly the coil CB_Md_b is wound, the greater the intensity of the magnetic field generated from the brush magnetic body CB_Md. For example, when the number of turns per length of the coil CB_Md_b is a first turn in the first section CB_Md_A1 of the brush magnetic body CB_Md and the number of turns per length of the coil CB_Md_b is a second turn in the second section CB_Md_A2 of the brush magnetic body CB_Md, the first turn may be less than the second turn.

In some embodiments, the number of turns per length of the coil CB_Md_b of the brush magnetic body CB_Md may be adjusted to adjust the intensity of the magnetic field generated in some sections of the brush magnetic body CB_Md. For example, as the number of turns per length of the coil CB_Md_b increases in a section of the brush magnetic body CB_Md where a relatively large amount of impurities are attached to the outer surface of the brush CBd, the cleaning efficiency of the brush CBd may be improved.

Although FIG. 8 illustrates that the second section CB_Md_A2 of the brush magnetic body CB_Md is located at the center of the brush CBd and the first sections CB_Md_A1 of the brush magnetic body CB_Md are positioned at both ends of the brush CBd, the arrangement of the first section CB_Md_A1 and the second section CB_Md_A2 of the brush magnetic body CB_Md is not limited thereto. The second section CB_Md_A2 may be located in a position where the amount of impurities attached to the brush CBd is large.

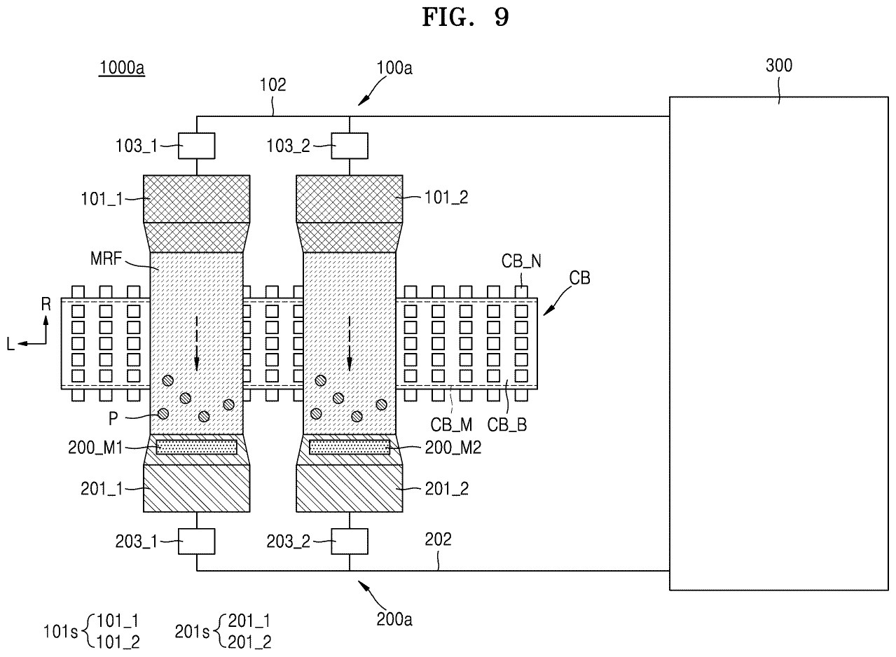

FIG. 9 is a schematic plan view of a brush cleaning apparatus 1000a according to embodiments.

Most components of the brush cleaning apparatus 1000a described below and materials constituting the components thereof are substantially the same as or similar to those described above with reference to FIG. 1. Therefore, for convenience of description, the differences between the brush cleaning apparatus 1000a of FIG. 9 and the brush cleaning apparatus 1000 of FIG. 1, described above, are mainly described.

Referring to FIG. 9, the brush cleaning apparatus 1000a may include a sprayer 100a, a suction device 200a, and the purifier 300. The brush cleaning apparatus 1000a may clean the brush CB to be cleaned by the cleaning solution MRF of which the flow direction is changed by the magnetic field. For example, the brush CB may include the brush magnetic body CB_M that generates the magnetic field.

For example, the brush cleaning apparatus 1000a may spray the cleaning solution MRF including the plurality of magnetic particles MRF_M (see FIG. 3) onto the brush CB including the brush magnetic body CB_M to remove the impurities P located on the outer surface of the brush CB from the brush CB.

The sprayer 100a may include a plurality of spray nozzles 101s arranged to spray the cleaning solution MRF to the brush CB, and a spray pipe 102 in communication with the plurality of spray nozzle 101s. The suction device 200a may include a plurality of suction nozzles 201s arranged to suck the cleaning solution MRF located on the outer surface of the brush CB, and a suction pipe 202 in communication with the plurality of suction nozzle 201s.

The number of spray nozzles 101s may be the same as the number of suction nozzles 201s. The number of spray nozzles 101s and the number of suction nozzles 201s are not limited to the numbers disclosed in FIG. 9.

The plurality of spray nozzles 101s may correspond to the plurality of suction nozzles 201s. For example, the cleaning solution MRF sprayed from each of the plurality of spray nozzles 101s may be sucked into the suction nozzle 201s corresponding to each spray nozzle 101s. In some embodiments, the plurality of spray nozzles 101s and the plurality of suction nozzles 201s may be spaced apart from each other with the brush CB therebetween.

In some embodiments, the cleaning solution MRF sprayed from the plurality of spray nozzles 101s may move along the outer surface of the brush CB to remove the impurities P attached to the outer surface of the brush CB. That is, the impurities P may be separated from the outer surface of the brush CB and may move together with the cleaning solution MRF. The suction device 200a may suck the impurities P and the cleaning solution MRF together.

The plurality of spray nozzles 101s may include a first spray nozzle 101_1 and a second spray nozzle 101_2. In some embodiments, the sprayer 100a may include a first spray pump 103_1 that adjusts the flow rate of the cleaning solution MRF sprayed from the first spray nozzle 101_1, and a second spray pump 103_2 that adjusts the flow rate of the cleaning solution MRF sprayed from the second spray nozzle 101_2.

In some embodiments, the output of the first spray pump 103_1 may be different from the output of the second spray pump 103_2. The flow rate of the cleaning solution MRF sprayed from the first spray nozzle 101_1 may be different from the flow rate of the cleaning solution MRF sprayed from the second spray nozzle 101_2. For example, as the output of the first spray pump 103_1 is greater than the output of the second spray pump 103_2, the flow rate of the cleaning solution MRF sprayed from the first spray nozzle 101_1 may be greater than that of the cleaning solution MRF sprayed from the second spray nozzle 101_2. However, the inventive concept is not limited thereto. The first spray nozzle 101_1 and the second spray nozzle 101_2 may be connected to one spray pump.

The plurality of suction nozzles 201s may include a first suction nozzle 201_1 corresponding to the first spray nozzle 101_1, and a second suction nozzle 201_2 corresponding to the second spray nozzle 101_2. The first suction nozzle 201_1 may be arranged to suck the cleaning solution MRF sprayed from the first spray nozzle 101_1, and the second suction nozzle 201_2 may be arranged to suck the cleaning solution MRF sprayed from the second spray nozzle 101_2.

In some embodiments, the suction device 200a may include a first suction magnetic body 200_M1 located on the first suction nozzle 201_1, and a second suction magnetic body 200_M2 located on the second suction nozzle 201_2. The first suction magnetic body 200_M1 may form the magnetic field at the inlet of the first suction nozzle 201_1, and the second suction magnetic body 200_M2 may form the magnetic field at the inlet of the second suction nozzle 201_2.

In some embodiments, the suction device 200a may include a first suction pump 203_1 that forms a negative pressure at the inlet of the first suction nozzle 201_1, and a second suction pump 203_2 that forms a negative pressure at the inlet the second suction nozzle 201_2. The output of the first suction pump 203_1 may be different from the output of the second suction pump 203_2. For example, the negative pressure formed at the inlet of the first suction nozzle 201_1 and the negative pressure formed at the inlet of the second suction nozzle 201_2 may be independently adjusted.

The first spray nozzle 101_1 and the second spray nozzle 101_2 may be arranged in a row in the long axis direction L of the brush CB. The first suction nozzle 201_1 and the second suction nozzle 201_2 may be arranged in a row in the long axis direction L of the brush CB. For example, the vertical level of the first spray nozzle 101_1 may be substantially the same as that of the second spray nozzle 101_2, and the vertical level of the first suction nozzle 201_1 may be substantially the same as that of the second suction nozzle 201_2.

For example, the first spray nozzle 101_1 may be spaced apart from the first suction nozzle 201_1 in the diametric direction R of the brush CB with the brush CB therebetween. The second spray nozzle 101_2 may be spaced apart from the second suction nozzle 201_2 in the diametric direction R of the brush CB with the brush CB therebetween.

In some embodiments, the direction from the first spray nozzle 101_1 to the first suction nozzle 201_1 may be the same as the direction from the second spray nozzle 101_2 to the second suction nozzle 201_2. The direction from the first spray nozzle 101_1 to the first suction nozzle 201_1 may be parallel to the direction from the second spray nozzle 101_2 to the second suction nozzle 201_2.

In some embodiments, the flow direction of the cleaning solution MRF sprayed from the first spray nozzle 101_1 may be the same as the flow direction of the cleaning solution MRF sprayed from the second spray nozzle 101_2. For example, the cleaning solution MRF sprayed from the first spray nozzle 101_1 may move counterclockwise along the outer surface of the brush CB, and the cleaning solution MRF sprayed from the second spray nozzle 101_2 may move counterclockwise along the outer surface of the bush CB.

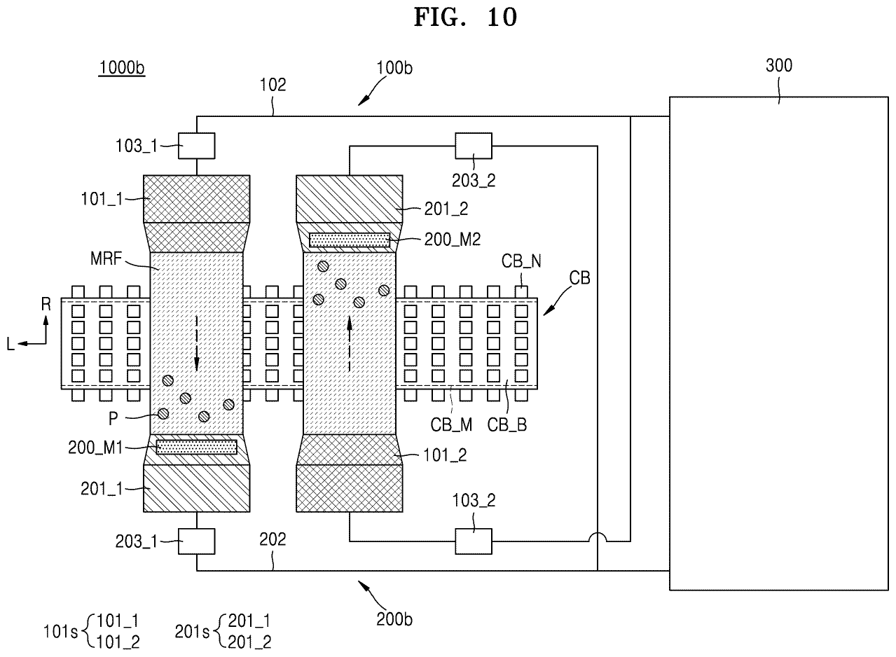

FIG. 10 is a schematic plan view of a brush cleaning apparatus 1000b according to embodiments.

Most components of the brush cleaning apparatus 1000b described below and materials constituting the components thereof are substantially the same as or similar to those described above with reference to FIG. 9. Therefore, for convenience of description, the differences between the brush cleaning apparatus 1000b of FIG. 10 and the brush cleaning apparatus 1000a of FIG. 9, described above, are mainly described.

Referring to FIG. 10, the brush cleaning apparatus 1000b may include a sprayer 100b, a suction device 200b, and the purifier 300. The brush cleaning apparatus 1000b may clean the brush CB to be cleaned through the cleaning solution MRF of which the flow direction is changed by the magnetic field. For example, the brush CB may include the brush magnetic body CB_M that generates the magnetic field.

The sprayer 100b may include the first spray nozzle 101_1 and the second spray nozzle 101_2. The suction device 200b may include the first suction nozzle 201_1 and the second suction nozzle 201_2. The cleaning solution MRF sprayed from the first spray nozzle 101_1 to the brush CB may be sucked into the first suction nozzle 201_1, and the cleaning solution MRF sprayed from the second spray nozzle 101_2 may be sucked into the second suction nozzle 201_2.

The second suction nozzle 201_2 and the first spray nozzle 101_1 may be arranged in a row in the long axis direction L of the brush CB. For example, the first spray nozzle 101_1 may not overlap with the second spray nozzle 101_2 in the long axis direction L and the diametric direction R of the brush CB. The first suction nozzle 201_1 may not overlap with the second suction nozzle 201_2 in the long axis direction L and the diametric direction R of the brush CB.

In some embodiments, the vertical level of the second suction nozzle 201_2 may be substantially the same as that of the first spray nozzle 101_1. The second suction nozzle 201_2 may overlap with the first spray nozzle 101_1 in the long axis direction L of the brush CB.

In some embodiments, the direction from the first spray nozzle 101_1 to the first suction nozzle 201_1 may be opposite to the direction from the second spray nozzle 101_2 to the second suction nozzle 201_2.

The flow direction of the cleaning solution MRF sprayed from the first spray nozzle 101_1 may be different from the flow direction of the cleaning solution MRF sprayed from the second spray nozzle 101_2. For example, the cleaning solution MRF sprayed from the first spray nozzle 101_1 may move counterclockwise along the outer surface of the brush CB, and the cleaning solution MRF sprayed from the second spray nozzle 101_2 may move clockwise along the outer surface of the brush CB.

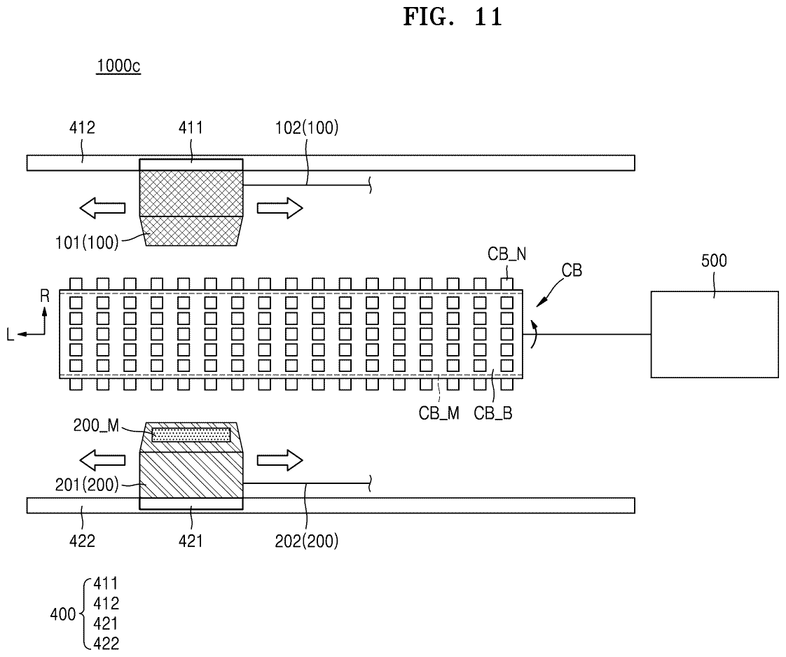

FIG. 11 is a schematic conceptual of a brush cleaning apparatus 1000c according to embodiments. In FIG. 11, the purifier 300 is omitted to show operations of the spray nozzle 101 and the suction nozzle 201.

Most components of the brush cleaning apparatus 1000c described below and materials constituting the components thereof are substantially the same as or similar to those described above with reference to FIG. 1. Therefore, for convenience of description, the differences between the brush cleaning apparatus 1000c of FIG. 11 and the brush cleaning apparatus 1000 of FIG. 1, described above, are mainly described.

Referring to FIG. 11 together with FIG. 1, the brush cleaning apparatus 1000c may further include the sprayer 100, the suction device 200, the purifier 300, a nozzle driver 400, and a brush rotator 500. The brush cleaning apparatus 1000c may include an apparatus for cleaning the brush CB through the cleaning solution MRF of which the flow direction is changed by the magnetic field.

The nozzle driver 400 may move the spray nozzle 101 of the sprayer 100 and the suction nozzle 201 of the suction device 200 in the long axis direction L of the brush CB. For example, the nozzle driver 400 may include a first rail 412 and a second rail 422 that extend lengthwise in the long axis direction L of the brush CB, and a first driving unit 411 moving in the long axis direction L of the brush CB along the first rail 412 and a second driving unit 421 moving in the long axis direction L of the brush CB along the second rail 422.

The first rail 412 and the second rail 422 may be spaced from each other with the brush CB, the spray nozzle 101, and the suction nozzle 201 therebetween. The first driving unit 411 may be coupled to the spray nozzle 101, and the second driving unit 421 may be coupled to the suction nozzle 201. When the first driving unit 411 moves along the first rail 412, the spray nozzle 101 coupled to the first driving unit 411 may move together therewith. When the second driving unit 421 moves along the second rail 422, the second suction nozzle 201 coupled to the second driving unit 421 may move together therewith.

For example, the spray nozzle 101 may move along the first rail 412 in the long axis direction L of the brush CB through the first driving unit 411, and the suction nozzle 201 may move along the second rail 422 in the long axis direction L of the brush CB through the second driving unit 421.

In some embodiments, the width of the inlet of the spray nozzle 101 of the sprayer 100 may be less than the length thereof in the long axis direction L of the brush CB. By moving the spray nozzle 101 of the sprayer 100 in the long axis direction L of the brush CB, the entire outer surface of the brush CB may be cleaned even when the spray nozzle 101 is smaller than the brush CB. In addition, the suction nozzle 201 may be positioned to correspond to the position of the spray nozzle 101, thereby preventing the cleaning solution MRF sprayed from the spray nozzle 101 from being lost.

In some embodiments, the sprayer 100 may further include a first flexible hose. The first flexible hose may be located between the spray nozzle 101 and the spray pipe 102 or between the spray pipe 102 and the purifier 300. Since the first flexible hose has a high degree of freedom of shape, the first flexible hose may reduce the restriction on the movement of the spray nozzle 101 when the spray nozzle 101 moves in the long axis direction L of the brush CB.

In some embodiments, the suction device 200 may further include a second flexible hose. The second flexible hose may be located between the suction nozzle 201 and the suction pipe 202 or between the suction pipe 202 and the purifier 300. Since the second flexible hose has a high degree of freedom of shape, the second flexible hose may reduce the restriction on the movement of the suction nozzle 201 when the suction nozzle 201 moves in the long axis direction L of the brush CB.

The brush rotator 500 may be connected to the brush CB to rotate the brush CB. The brush rotator 500 may rotate the brush CB clockwise or counterclockwise with the long axis of the brush CB as a rotational axis. In some embodiments, the brush rotator 500 may rotate the brush CB so that the entire outer surface of the brush CB is cleaned by the cleaning solution MRF. In some embodiments, the brush rotator 500 may include an electromagnetic motor, a rotary motor, or a spindle motor.

For example, when the cleaning solution MRF moves along the outer surface of the brush CB, some areas of the brush CB may not be cleaned when the brush CB does not rotate. The brush rotator 500 may rotate the brush CB clockwise or counterclockwise to clean the entire outer surface of the brush CB.

In addition, the brush rotator 500 may rotate the brush CB to enable the irregular contact between the cleaning solution MRF and the brush CB, thereby increasing the brush cleaning efficiency of the brush cleaning apparatus 1000c.

In some embodiments, the speed at which the brush rotator 500 rotates the brush CB, e.g., the linear speed at a point on the outer surface of the brush CB, may be less than the speed at which the cleaning solution MRF moves onto the outer surface of the brush CB.

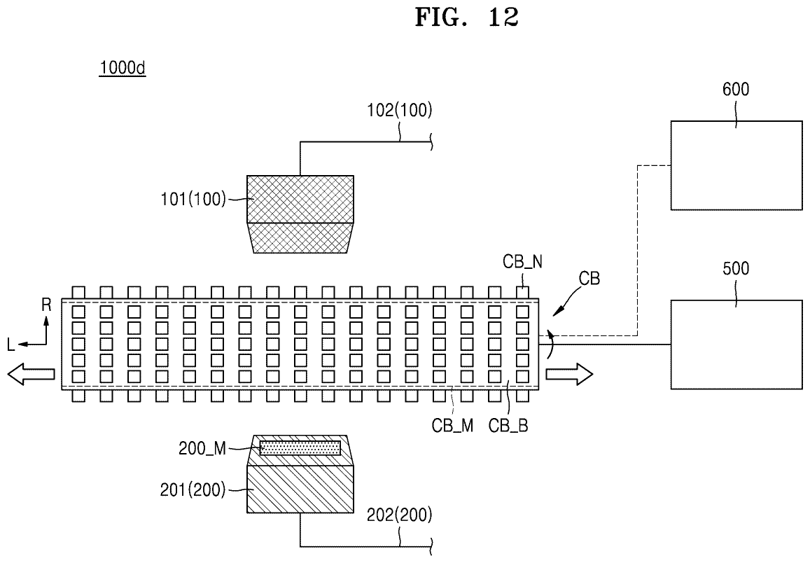

FIG. 12 is a schematic conceptual diagram of a brush cleaning apparatus 1000d according to embodiments. In FIG. 12, the purifier 300 is omitted to show the operation of the brush CB.

Most components of the brush cleaning apparatus 1000d described below and materials constituting the components thereof are substantially the same as or similar to those described above with reference to FIG. 11. Therefore, for convenience of description, the differences between the brush cleaning apparatus 1000d of FIG. 12 and the brush cleaning apparatus 1000c of FIG. 11, described above, are mainly described.

Referring to FIG. 12 together with FIG. 1, the brush cleaning apparatus 1000d may further include the sprayer 100, the suction device 200, the purifier 300, the brush rotator 500, and a brush driver 600. The brush cleaning apparatus 1000d may include an apparatus for cleaning the brush CB through the cleaning solution MRF of which the flow direction is changed by the magnetic field.

The brush cleaning apparatus 1000d of FIG. 12 includes the brush driver 600, instead of the nozzle driver 400 of the brush cleaning apparatus 1000c of FIG. 11. The brush driver 600 may be connected to the brush CB to move the brush CB in the long axis direction L of the brush CB.

The brush cleaning apparatus 1000d may move the brush CB in the long axis direction L of the brush CB relative to the spray nozzle 101 and the suction nozzle 201 by moving the brush CB in the long axis direction L of the brush CB while fixing positions of the spray nozzle 101 of the sprayer 100 and the suction nozzle 201 of the suction device 200. Therefore, the spray nozzle 101 may spray the cleaning solution MRF to the entire outer surface of the brush CB.

In some embodiments, the brush driver 600 may include an actuator. In some embodiments, the brush driver 600 may include a grabber that fixes both ends of the brush CB and may move the grabber in the long axis direction L of the brush CB to move the brush CB together with the grabber.

While the inventive concept has been particularly shown and described with reference to embodiments thereof, it will be understood that various changes in form and details may be made therein without departing from the spirit and scope of the following claims.

What is claimed is:

1. A brush cleaning apparatus comprising:
a sprayer comprising a spray nozzle configured to spray a cleaning solution comprising a plurality of magnetic particles and a carrier fluid onto a brush, and a spray pipe in communication with the spray nozzle;
a suction device comprising a suction nozzle configured to suck the cleaning solution disposed on an outer surface of the brush, and a suction pipe in communication with the suction nozzle; and
a purifier connected to the spray pipe of the sprayer and the suction pipe of the suction device and configured to separate the plurality of magnetic particles from the cleaning solution.

2. The brush cleaning apparatus of claim 1, wherein the purifier comprises a purifying magnetic body configured to apply an attractive force to the plurality of magnetic particles of the cleaning solution, and
the cleaning solution introduced through the suction pipe is configured to pass through a magnetic field generated by the purifying magnetic body and flow out through the spray pipe.

3. The brush cleaning apparatus of claim 2, wherein the purifier further comprises a carrier fluid supply pipe for replenishing the cleaning solution with the carrier fluid, and a discharge pipe for discharging a part of the cleaning solution, and
the purifying magnetic body is closer to the spray pipe of the sprayer than the discharge pipe.

4. The brush cleaning apparatus of claim 1, wherein the spray nozzle of the sprayer is spaced apart from the suction nozzle of the suction device with the brush therebetween.

5. The brush cleaning apparatus of claim 4, wherein the cleaning solution sprayed from the spray nozzle of the sprayer to the brush is configured to move along the outer surface of the brush and being sucked into the suction nozzle of the suction device.

6. The brush cleaning apparatus of claim 1, wherein the suction device further comprises a suction magnetic body located at the suction nozzle to apply an attractive force to the cleaning solution through the suction nozzle.

7. The brush cleaning apparatus of claim 1, wherein the suction device further comprises a suction pump configured to create a negative pressure in the suction nozzle.

8. The brush cleaning apparatus of claim 1, wherein one or more of the plurality of magnetic particles of the cleaning solution comprise a magnetic material and a non-magnetic material surrounding the magnetic material.

9. The brush cleaning apparatus of claim 1, wherein the brush comprises a body in a cylindrical shape, and a brush magnetic body extending in a long axis direction of the body and passing through the body.

10. The brush cleaning apparatus of claim 9, wherein the brush magnetic body comprises a first section and a second section, and
an intensity of a magnetic field generated in the second section of the brush magnetic body is greater than an intensity of a magnetic field generated in the first section of the brush magnetic body.

11. The brush cleaning apparatus of claim 9, wherein the brush magnetic body of the brush comprises a core and a coil surrounding the core.

12. A brush cleaning apparatus comprising:
a sprayer comprising a plurality of spray nozzles configured to spray a cleaning solution containing a plurality of magnetic particles and a carrier fluid onto a brush, and a spray pipe in communication with the plurality of spray nozzles;
a suction device comprising a plurality of suction nozzles configured to suck the cleaning solution located on an outer surface of the brush, and a suction pipe in communication with the plurality of suction nozzles; and
a purifier connected to the spray pipe of the sprayer and the suction pipe of the suction device and configured to separate the plurality of magnetic particles from the cleaning solution,
wherein the plurality of spray nozzles of the sprayer comprise a first spray nozzle and a second spray nozzle, and
the plurality of suction nozzles of the suction device comprise a first suction nozzle configured to suck the cleaning solution sprayed from the first spray nozzle, and a second suction nozzle configured to suck the cleaning solution sprayed from the second spray nozzle.

13. The brush cleaning apparatus of claim 12, wherein a direction from the first spray nozzle toward the first suction nozzle is same as a direction from the second spray nozzle toward the second suction nozzle.

14. The brush cleaning apparatus of claim 12, wherein a direction from the first spray nozzle to the first suction nozzle is opposite to a direction from the second spray nozzle to the second suction nozzle.

15. The brush cleaning apparatus of claim 12, wherein a flow rate of the cleaning solution sprayed through the first spray nozzle of the sprayer is different from a flow rate of the cleaning solution sprayed through the second spray nozzle of the sprayer.

16. The brush cleaning apparatus of claim 12, further comprising a nozzle driver configured to move the plurality of spray nozzles of the sprayer and the plurality of suction nozzles of the suction device in a long axis direction of the brush.

17. The brush cleaning apparatus of claim 12, further comprising a brush driver configured to move the brush in a long axis direction of the brush.

18. The brush cleaning apparatus of claim 12, further comprising a brush rotator configured to rotate the brush with a long axis of the brush as a rotational axis.

19. A brush cleaning apparatus comprising:
a sprayer comprising at least one spray nozzle configured to spray a cleaning solution comprising a plurality of magnetic particles and a carrier fluid onto a brush, and a spray pipe in communication with the at least one spray nozzle;
a suction device comprising at least one suction nozzle configured to suck the cleaning solution located on an outer surface of the brush, a suction pipe in communication with the at least one suction nozzle, and a suction magnetic body located on the at least one suction nozzle; and
a purifier comprising a frame including a processing space in communication with the spray pipe of the sprayer and the suction pipe of the suction device, and a purifying magnetic body configured to form a magnetic field in the processing space,
wherein the brush comprises a body in a cylindrical shape, and a brush magnetic body extending in a long axis direction of the body and passing through the body, and
each of the brush magnetic body of the brush, the suction magnetic body of the suction device, and the purifying magnetic body of the purifier is configured to apply an attractive force to the plurality of magnetic particles of the cleaning solution.

20. The brush cleaning apparatus of claim 19, wherein an intensity of a magnetic field of the suction magnetic body of the suction device is greater than an intensity of a magnetic field of the brush magnetic body of the brush.
